(19) United States
(12) Patent Application Publication
(10) Pub. No.: US 2012/0225546 A1
(43) Pub. Date: Sep. 6, 2012

(54) METHOD OF MANUFACTURING NONVOLATILE SEMICONDUCTOR STORAGE DEVICE

(75) Inventor: Eiji KAMIYA, Yokkaichi (JP)

(73) Assignee: Kabushiki Kaisha Toshiba, Tokyo (JP)

(21) Appl. No.: 13/410,743

(22) Filed: Mar. 2, 2012

(30) Foreign Application Priority Data
Mar. 3, 2011 (JP) 2011-046342

(51) Int. Cl. H01L 21/283

(52) U.S. Cl. 438/591; 257/E21.19

(57) ABSTRACT

A method of manufacturing a nonvolatile semiconductor storage device includes applying a first mask lying across a line pattern located in a first region for forming a first gate electrode and a line pattern located in a second region for forming a second gate electrode; slimming sidewalls of unmasked line patterns; forming a blanket film across the first region and the second region and partially removing the blanket film so as to remain along the slimmed sidewalls of the line patterns; applying a second mask above the line patterns located in the first region and removing the line patterns in the second region such that the masked line patterns in the first region remain; anisotropically etching the first film using the blanket film and the remaining line patterns as a mask; and etching a charge storage layer using the first film as a mask.

### CROSS-REFERENCE TO RELATED APPLICATION(S)

This application is based upon and claims the benefit of priority from Japanese Patent Application No. 2011-046342, filed on, Mar. 3, 2011 the entire contents of which are incorporated herein by reference.

### FIELD

Exemplary embodiments disclosed herein generally relate to a method of manufacturing nonvolatile semiconductor storage device.

### BACKGROUND

Structures of nonvolatile semiconductor storage devices, typically the gate electrodes, are microfabricated using a photolithography process. Normally, a replicate of the photolithographic patterns are transferred from the resist to the underlying mask pattern to form the gate electrodes. When forming sublithographic features, a sidewall transfer process (SWT) is typically used which allows formation of patterns that are narrower in width and pitch as compared to patterns formed by a normal photolithography process.

For instance, gate electrodes for memory cell transistors i.e. memory cell gate electrodes and gate electrodes for select transistors i.e. select gate electrodes have different electrical property requirements. Thus, the lengths of the memory cell gate electrodes and select gate electrodes are varied to meet such different requirements.

Because of such variance in the length of the gate electrodes, relatively greater space is often required between the memory cell gate electrode and the select gate electrode as compared to between the memory cell gate electrodes in order to control the lengths of the gates of the memory cell electrode and select gate electrode as required. In view of the requirements for smaller devices and design rules and for meeting the device property requirements of different types of transistors, controllability of the spacing between different types of gate electrodes is desired especially in a topography including the select gate electrode having a relatively wide width and other types of transistors, typically memory cell transistors having a relatively smaller width.

### BRIEF DESCRIPTION OF THE DRAWINGS

FIG. 1 is a partial schematic plan view of the electrical configuration of a memory cell region of a NAND flash memory according to a first embodiment;

FIG. 2 is a partial plan view schematically illustrating the structure of the memory cell region;

FIG. 3 is a schematic cross sectional view of taken along line 3A-3A of FIG. 2;

FIGS. 4 to 13 each corresponds to FIG. 3 and indicates one phase of the manufacturing process flow; and

FIGS. 14 to 22 each corresponds to FIG. 3 and indicates one phase of the manufacturing process flow according to a second embodiment.

### DETAILED DESCRIPTION

In one exemplary embodiment, a method of manufacturing a nonvolatile semiconductor device includes preparing a semiconductor substrate having a gate insulating film formed thereabove; forming a charge storage layer above the gate insulating film, the charge storage layer being used as a first gate electrode of a first transistor and as a second gate electrode of a second transistor; forming a first film and a second film in the listed sequence above the charge storage layer; patterning the second film into a line and space pattern including a plurality of line patterns and a plurality of space patterns; applying a first mask lying across the line pattern located in a first region for forming the first gate electrode and the line pattern located in a second region for forming the second gate electrode; slimming sidewalls of unmasked line patterns; forming a blanket film across the first region and the second region and partially removing the blanket film so as to remain along the slimmed sidewalls of the line patterns; applying a second mask above the line patterns located in the first region and removing the line patterns located in the second region such that the masked line patterns located in the first region remain; anisotropically etching the first film using the blanket film and the remaining line patterns as a mask; and etching the charge storage layer using the first film as a mask to form the first and the second gate electrodes.

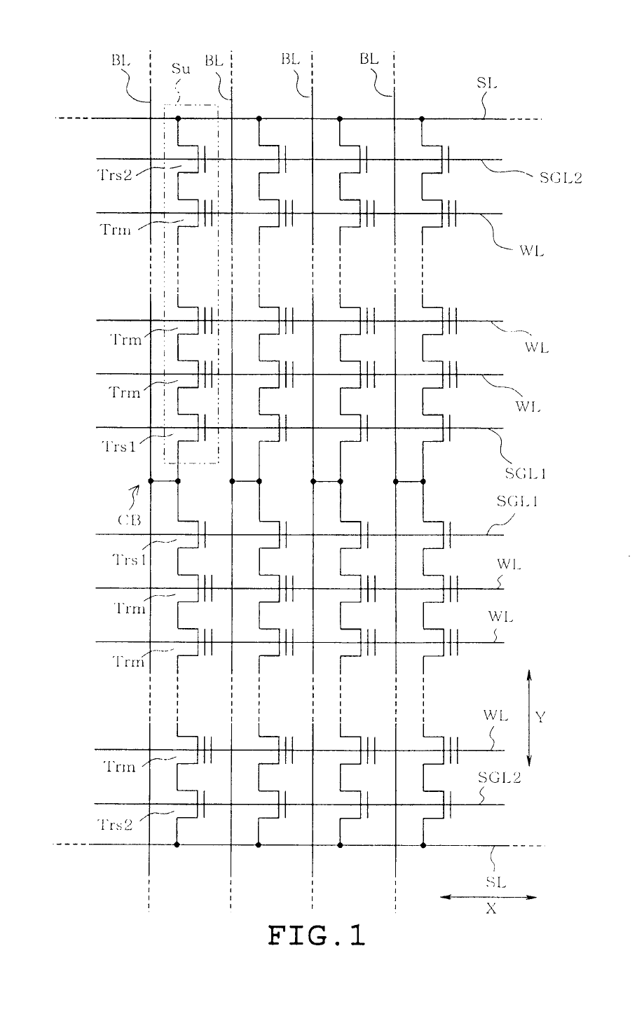

Embodiments are described hereinafter through a NAND flash memory application with references to FIGS. 1 to 13. Elements that are identical or similar are represented by identical or similar reference symbols across the figures. The drawings are not drawn to scale and thus, do not reflect the actual measurements of the features such as the correlation of thickness to planar dimensions and the relative thickness of different layers.

First, a description is given on the electrical configuration of a NAND flash memory. FIG. 1 is a partial equivalent circuit representation of a memory cell array formed in a memory cell region of NAND flash memory 1.

The memory cell array is a collection of units of NAND cells also referred to as NAND cell units Su or NAND strings arranged in rows and columns. NAND cell unit Su comprises a multiplicity of series connected memory cell transistors Trm, such as 64 in number, situated between a couple of select transistors Trs1 and Trs2 that are located at Y-direction ends of NAND cell unit Su. The neighboring memory cell transistors Trm within NAND cell unit Su share their source/drain regions.

The X-direction aligned memory cell transistors Trm shown in FIG. 1 are interconnected by common word line WL also referred to as control gate line, whereas the X-direction aligned select transistors Trs1 are electrically interconnected by common select gate line SGL1 and likewise, the X-direction aligned select transistors Trs2 are electrically interconnected by common select gate line SGL2.

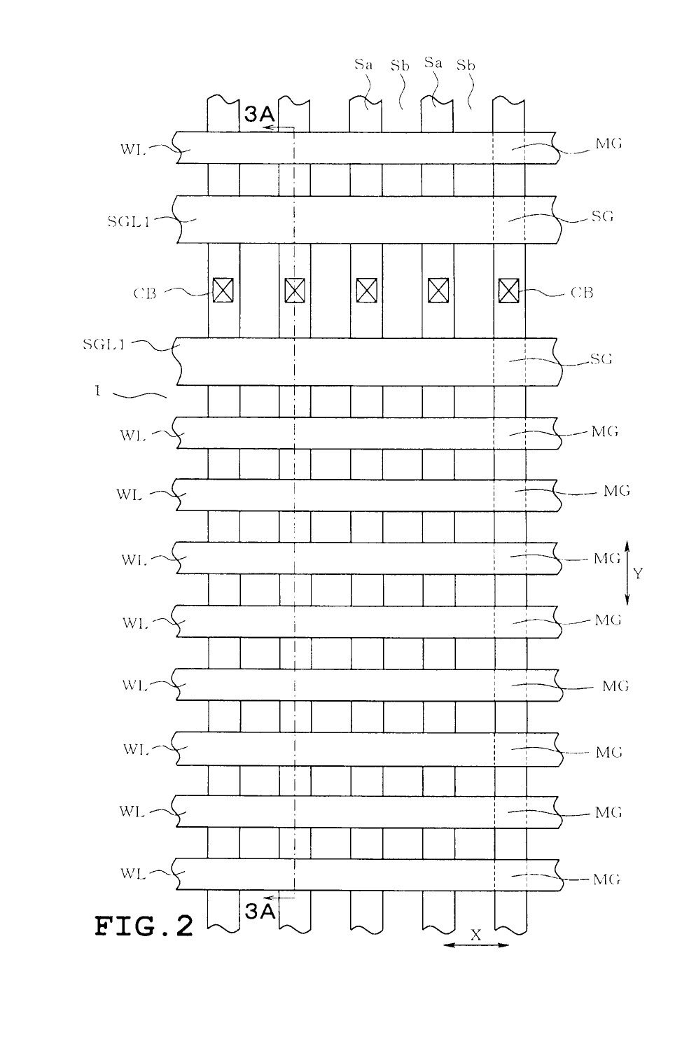

The drain of each select transistor Trs1 is coupled to bit line BL by way of bit line contact CB in FIG. 2. Bit line BL extends in the Y direction orthogonal to the X direction shown in FIG. 1. The source of select transistor Trs2 is coupled to source line SL extending in the X-direction.

FIG. 2 provides a planar layout of the memory cell region in part. As shown, multiplicity of isolation regions Sb run in the Y direction as viewed in FIG. 2 of silicon substrate 1, or more generally, semiconductor substrate 1. Isolation regions Sb are separated from one another in the X direction as viewed in FIG. 2 to isolate active areas Sa, running in the Y-direction, by a predetermined space interval in the X direction. The isolation typically employs a shallow trench isolation scheme.

Multiplicity of word lines WL, spaced from one another in the Y direction by a predetermined spacing, extend in the X direction as viewed in FIG. 2 which is the direction orthogonal to the Y direction in which active area Sa extends. Above active area Sa intersecting with word line WL, memory cell gate electrode MG of memory cell transistor Trm is formed. Above active area Sa intersecting with select dateline SGL1, select gate electrode SC of select transistor Trs 1 is formed. Select gate electrode SG is also referred to as a first gate electrode and select transistor trs1 is also referred to as a first transistor. Memory cell gate electrode MG is also referred to as a second gate electrode and memory cell transistor Trm is also referred to as a second transistor.

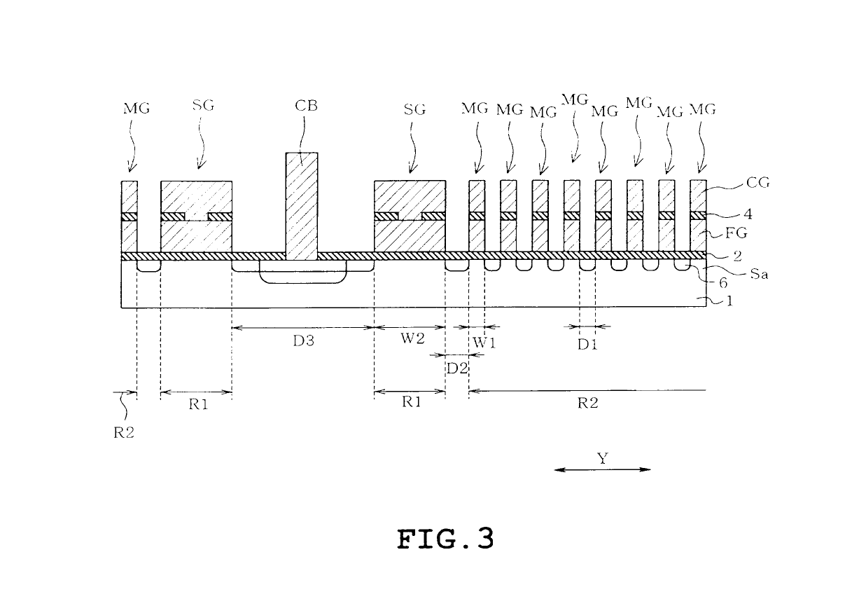

FIG. 3 partially illustrates a vertical cross sectional view taken along line 3A-3A of FIG. 2. FIG. 3 shows a Y-directional vertical cross section of gate electrode MG of memory cell transistor Trm and select gate electrode SG of select transistor Trs1.

As shown in FIG. 3, multiplicity of gate electrodes MG is disposed, with predetermined spacing therebetween, above semiconductor substrate 1 via gate insulating film 2. As mentioned earlier, cell unit Su comprises gate electrodes MG disposed between a pair of gate electrodes SG. Thus, in the example shown in FIG. 1, a pair of gate electrodes SG of select transistors Trs1 interposes gate electrodes MG of memory cell transistors Trm located in adjacent cell units Su.

As shown in FIG. 3, when the Y-directional width of gate electrode MG is represented by W1 and the Y-directional width of gate electrode SG is represented by W2, W1<W2. When the Y-directional spacing between gate electrode MG is represented by D1; the Y-directional spacing between gate electrodes MG and SG is represented by D2; and the Y-directional spacing between gate electrodes SC is represented by D3, D1<D2<D3.

Gate electrode MG formed above semiconductor substrate 1 via gate insulating film (first insulating film) 2 comprises a stack of floating gate electrode (charge storage layer) FG, intergate insulating film (second insulating film) 4, and control gate electrode CC.

Floating gate electrode VG is typically made of polysilicon film 3 doped with impurities. Intergate insulating film 4 is typically made of ONO (Oxide-Nitride-Oxide) film. Control gate electrode CG is typically made of polysilicon film 5 doped with impurities to serve as a conductive film, but may also have a silicide layer comprising tungsten silicide, cobalt silicide, or nickel silicide on top of it to reduce the level of resistance. In order to highlight the features of the first embodiment, control gate electrode CG comprising polysilicon film 5 is employed.

As can be seen in FIG. 3, select gate electrode SG is substantially identical in structure to gate electrode MG with the exception of an opening formed in intergate insulating film 4 to establish an electrical contact between polysilicon films 3 and 5.

In the surface layer of semiconductor substrate 1 situated between gate electrodes MG and between select gate electrode SC and gate electrode MG, impurity diffusion region 6 is formed as required to serve as a source/drain region. Between select gate electrodes SG, impurity diffusion region 6 is configured as an LDD (Lightly Doped Drain) structure and establishes an electrical contact with bit line contact CB formed above it. Gate electrode MG and select gate electrode SG structured as described above are formed by a sidewall transfer (SWT) process detailed hereinafter. SWT allows formation of small features such as width W1 of gate electrode MG, spacing D1 between gate electrodes MG, and spacing D2 between gate electrode MG and select gate electrode SG as shown in FIG. 3, which are difficult to form with an ordinary photolithography process. Because spacing D2, serving as a boundary between gate electrode MG and select gate electrode SG, is narrowed by the use of SWT, memory cell unit Su is reduced in size.

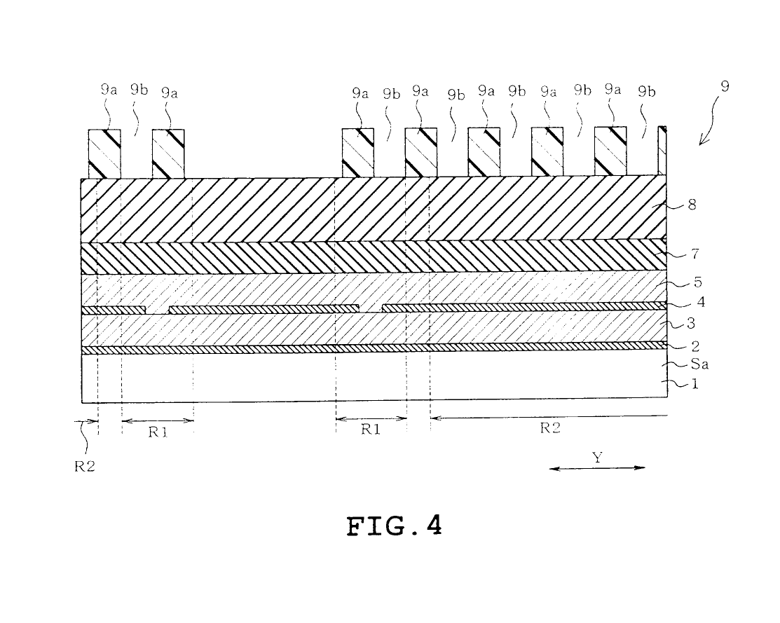

Next, the process flow of manufacturing the above described structure is described with reference to FIGS. 4 to 13. Description given hereinafter highlights the features of the first embodiment and may include additional steps or exclude some of the described steps if not required. The steps may be rearranged in sequence if practicable.

FIG. 4 schematically illustrates a laminate which is ultimately processed into the structure illustrated in FIG. 3. The process flow begins with formation of gate insulating film 2, typically comprising a silicon oxide film, in active region Sa of semiconductor substrate 1. Above gate insulating film 2, layers of films to be processed into select gate electrodes SG and memory cell gate electrodes MG are laminated so as to lie across the regions designed to form select gate electrodes SG represented as select gate electrode regions R1 also referred to as first regions and the regions designed to form memory cell gate electrodes MG represented as memory cell gate regions R2 also referred to as second regions.

The laminate includes polysilicon film 3, intergate insulating film 4, and polysilicon film 5. Intergate insulating film 4 situated in select gate region R1 has an opening formed through it during lamination. The opening allows electrical contact between the underlying polysilicon film 3 and the overlying polysilicon film 5.

Next, silicon nitride film 7 also referred to as a first film is deposited above polysilicon film 5 by LP-CVD (Low Pressure Chemical Vapor Deposition). Then, silicon oxide film 8 typically comprising TEOS (Tetra ethoxysilane) also referred to as a second film is deposited above silicon nitride film 7 by CVD.

Next, as shown in FIG. 4, resist 9 is formed above silicon oxide film 8. Resist 9 is thereafter patterned into a line and space pattern including a plurality offline patterns 9a and space patterns 9b extending in a straight line normal to the page of FIG. 4. The width of each line pattern 9a and the space between line patterns 9a are on the order of several tens of nanometers and thus, can be patterned substantially at the resolution limit of a normal photolithography process.

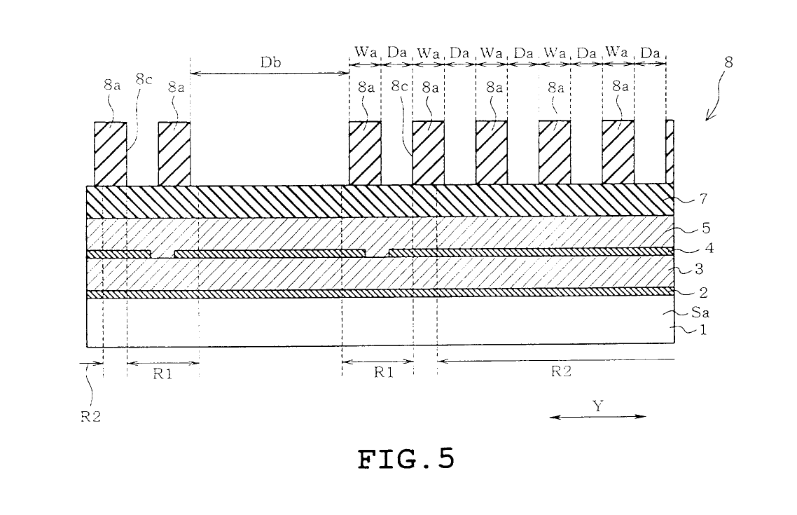

Then, as shown in FIG. 5, silicon oxide film 8 is anisotropically etched typically by RIE (Reactive Ion etching) using the patterned resist 9 as a mask. As a result, silicon oxide film 8 is patterned into a line and space pattern in which width of line pattern 8a is represented by Wa and spacing between the adjacent line patterns 8a is represented by Da, where width Wa and spacing Da are substantially equal. Spacing Da between each of line patterns 8a is substantially constant. Dimensioning the line and space pattern such that width Wa and spacing Da establish a 1:1 ratio is favorable to facilitate microfabrication.

As can be seen in FIG. 5, width Wa of line pattern 8a is narrower than the width of select gate region R1. FIG. 5 exemplifies a single line pattern 8a being formed in a single select gate region R1. Spacing Db between line patterns 8a residing in adjacent select gate regions R1 is greater than spacing Da and width Wa.

As shown in FIG. 5, the line and space pattern is formed such that line pattern 8a located in select gate region R1 and sidewall 8c of the first encountered line pattern 8a in the adjacent memory cell gate region 52, in other words, the second line pattern 8a counted from the edge of spacing Db substantially coincides with the sidewall of select gate electrode SG, stated differently, the boundary of select gate region R1.

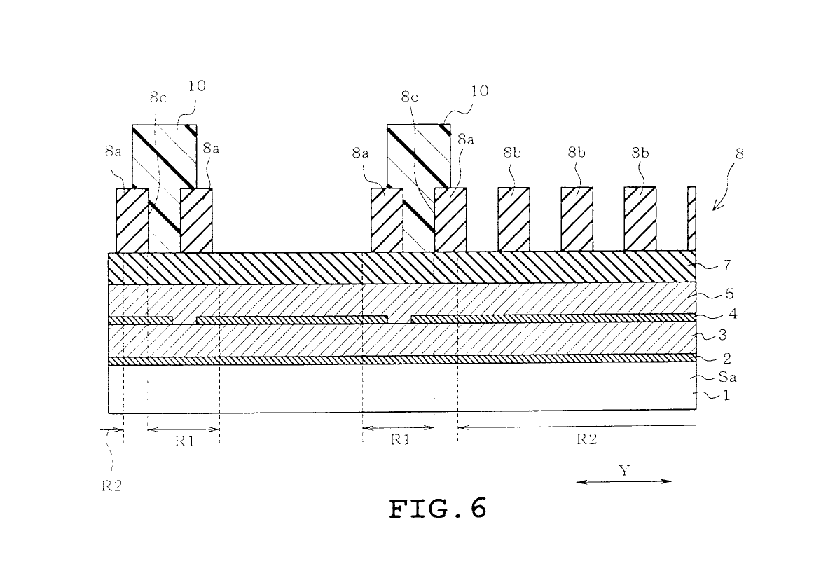

Next, as shown in FIG. 6, resist pattern 10 is formed so as to lie across spacing Da between line pattern 8a located in select gate region R1 and the first encountered, in other words, the nearest line pattern 8a in the adjacent memory cell gate region R2. First embodiment exemplifies a case in which resist pattern 10 is formed across spacing Da between the first and the second line pattern 8a counted from spacing Db. Resist pattern 10 serves as a first mask that covers sidewall 8c of line pattern 8a.

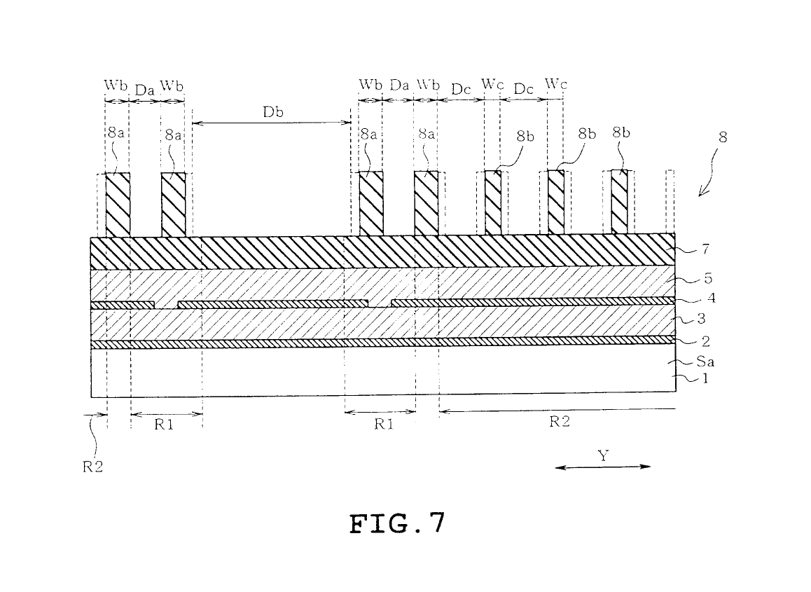

Next, as shown in FIG. 7, line pattern 8a is slimmed typically by wet etching from the outer sidewalls. The inner sidewalls of the first and second line pattern mentioned earlier are not slimmed because they are covered by resist pattern 10.

Further, spacing Da between the first and the second line patterns 8a is maintained because the inner sidewalls of the first and the second line patterns are not slimmed. Because the outer sidewall of the first and the second line patterns 8a are slimmed, the width of the first and the second line patterns 8a are reduced from Wa Lo Wb, i.e. width Wa>width Wb. The rest of line patterns hereinafter referred to as line patterns 8b, being slimmed on both of their inner and outer sidewalls, are reduced to width Wc which is less than width Wb, i.e. width Wb>width Wc. Further, spacing Dc between line patterns 8b is increased to become greater than spacing Da. Thereafter, resist pattern 10 is removed typically by ashing.

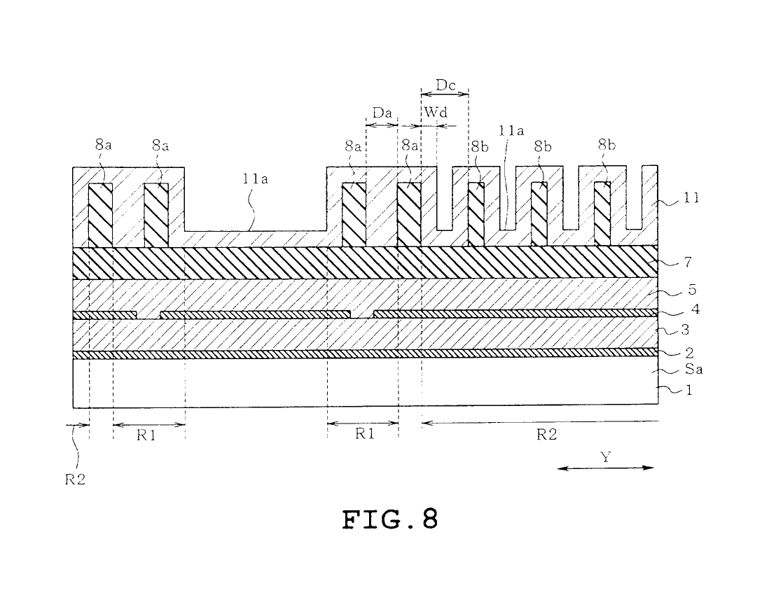

Then, as shown in FIG. 8, amorphous silicon film 11, later processed into a sidewall film, is conformally blanketed in thickness Wd along the sidewalls and the upper surfaces of line patterns 8a and 8b as well as the upper surface of silicon nitride film 7.

Thickness Wd may be controlled so as to meet the relations 2×thickness Wd≈spacing Da and 3×thickness Wd≈spacing DC with spacing Da and spacing Dc. When these relations are met, every spacing Da between line patterns 8a can be filled with amorphous silicon film 11. Further, amorphous silicon film 11, when formed to meet the foregoing relations, defines recess 11a within spacing Db and spacing Dc (>spacing Da).

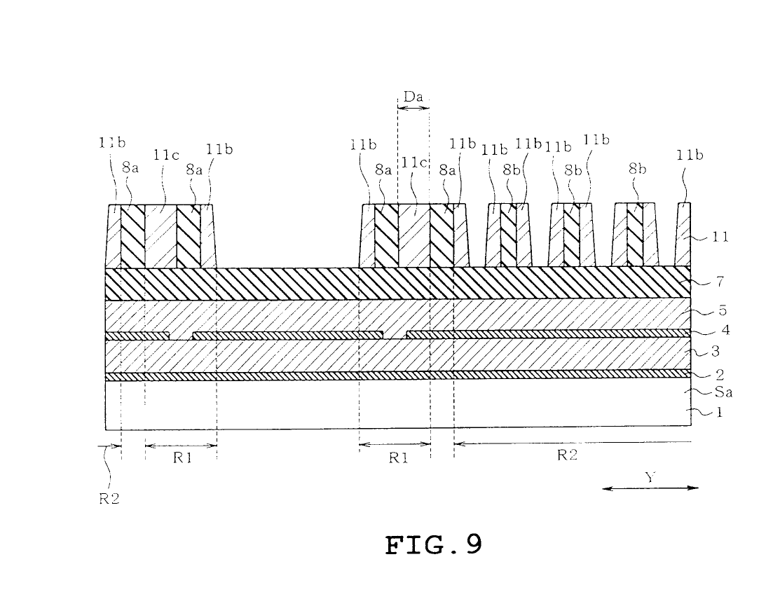

Next, amorphous silicon film 11 is anisotropically etched typically by RIE so as to remain as sidewall films as shown in FIG. 9. More specifically, amorphous silicon film 11 formed along the upper surfaces of line patterns 8a and 8b is removed as well as amorphous silicon film 11 at the bottom of recess 11a within spacing Dc to partially expose silicon nitride film 7 within spacing Dc. Thus, spacer 11b is formed along the sidewalls of each line pattern 8a.

Spacing Da within select gate region R1 was filled with amorphous silicon film 11 blanketed in FIG. 8. Thus, amorphous silicon film 11 stays filled between line patterns 8a, i.e. within spacing Da, as gap fill 11c even after the anisotropic etching shown in FIG. 9.

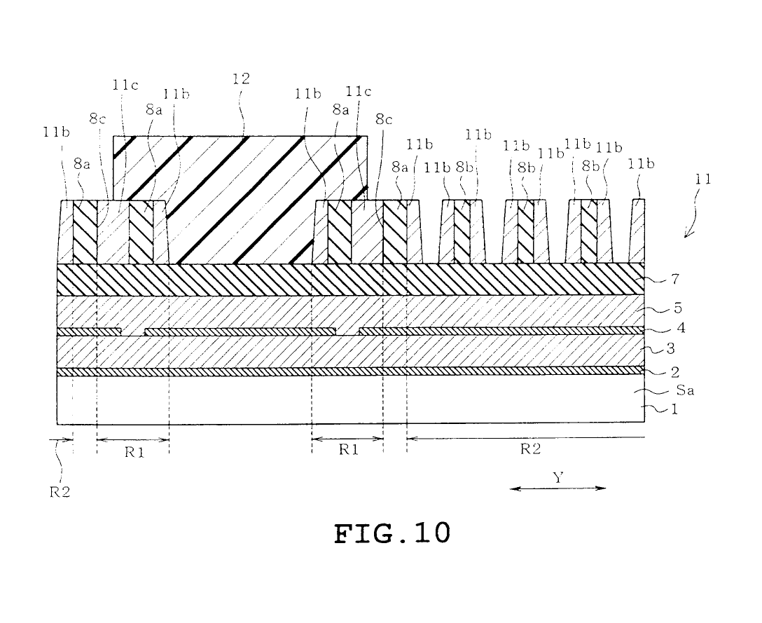

Next, as shown in FIG. 10, resist is coated over the processed laminate. The resist is thereafter patterned into resist pattern 12 that lies across the adjacent select gate regions R1 such that its sidewall is located above a portion of gap fill 11c. Resist pattern 12 serves as a second mask for covering the upper surface of line pattern 8a formed in select gate region R1 but does not cover the aforementioned sidewall 8c of line pattern 8a.

FIG. 10 of the first embodiment exemplifies a structure in which resist pattern 12 lies across a pair of adjacent select gate regions R1. Alternatively, a dedicated resist pattern 12 may be provided for each select gate region R1 as long as sidewall 8c of line pattern 8a stays uncovered.

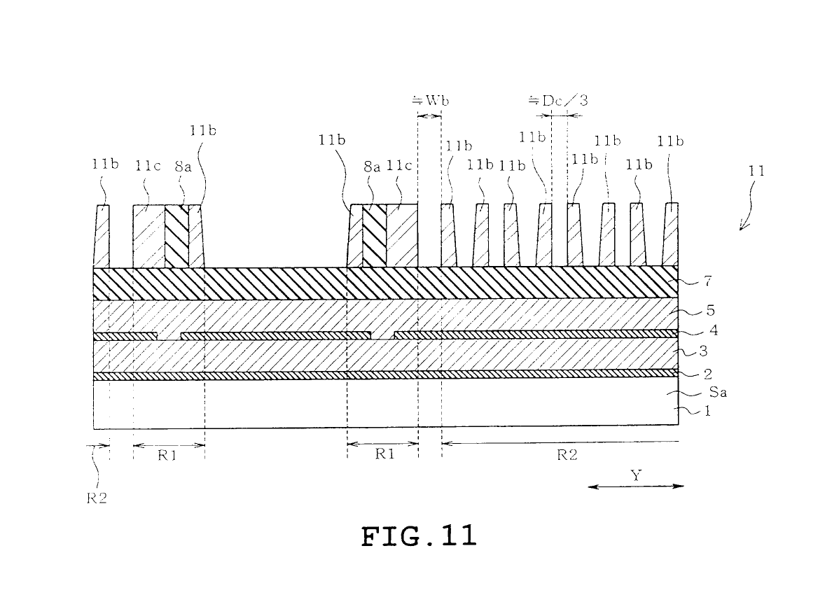

Then, as shown in FIG. 11, line patterns 8a and 8b uncovered by resist pattern 12 are selectively removed typically by wet etching. Spacer 11b and gap fill 11c shown in FIG. 11 are remnants of amorphous silicon film 11 and the underlying layer is silicon nitride film 7. Thus, the wet etching of line patterns 8a and 8b comprising silicon oxide film 8 is carried out with higher selectivity to resist pattern 12, amorphous silicon film 11, and silicon nitride film 7.

As a result, line patterns 8a and 8b serving as the core in SWT is removed except for lines 8a within select gate region R1. Line patterns 8a removed in this case are line patterns 8a located beside the edges of select gate regions R1. Then, resist pattern 12 is removed by aching.

FIG. 11 shows the resulting structure in which the width of select gate region R1 is configured as the sum of width of spacer 11b (≈Dc/3≈Wd); width Wb of line pattern 8a; and width Da of gap fill 11c. Memory cell gate region R2 is configured such that the width of each gate electrode MG is controlled to the width of spacer 11b (≈Dc/3≈Wd). Further, while controlling the spacing between each spacer 11b to approximately Dc/3, the spacing between gap fill 11c within select gate region R1 and spacer 11b of the adjacent memory cell gate region R2 is controlled to substantially equal width Wb of line pattern 8a.

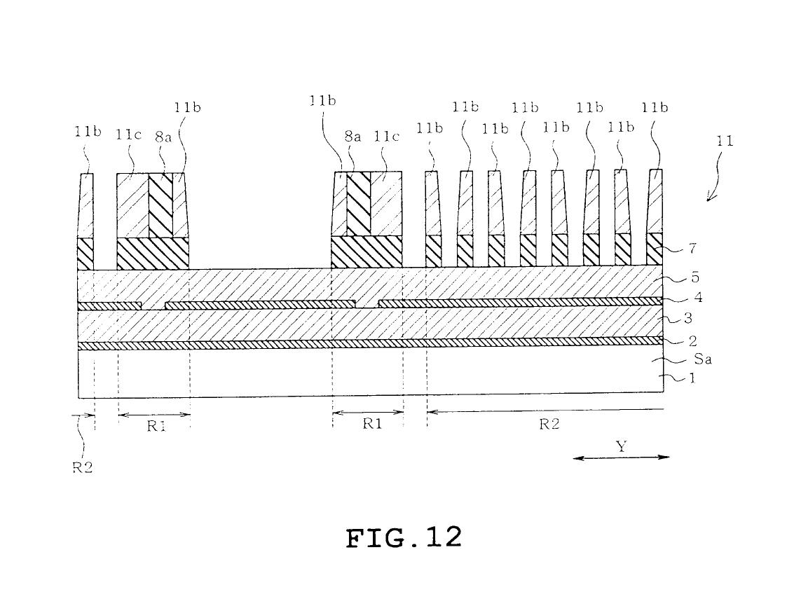

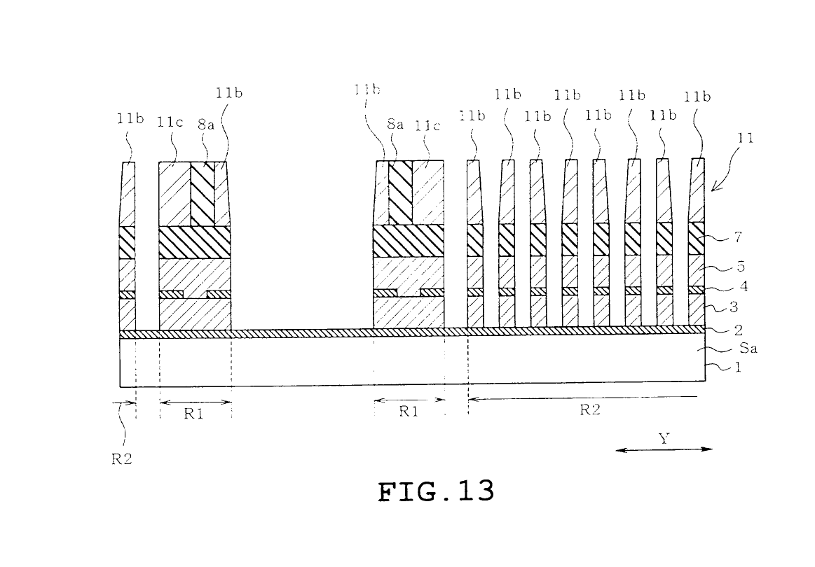

Then, as shown in FIG. 12, using the processed films as masks, silicon nitride film 7 is anisotropically etched typically by RIE. Then, as shown in FIG. 13, using the etched silicon nitride film 7 as a mask, the laminate of polysilicon film 5, intergate insulating film 4, and polysilicon film 3 is anisotropically etched typically by RIE. The laminated films 3 to 5 are thus, separated in the Y direction to form gate electrodes MG and SG.

Though not described in detail, the following steps are performed to fabricate the remaining structures illustrated in FIG. 3 which are not in close relevance with the features of the first embodiment. Impurities are implanted as required between the pillars of laminate films 3 to 5 by ion implantation. Then, the implanted impurities are thermally treated to obtain impurity diffusion region 6. Thereafter, line pattern 8a, spacer 11b, gap fill 11c, and silicon nitride film 7 are removed. Then, interlayer insulating film not shown is formed between gate electrodes MG and between gate electrodes MG and SG. Thereafter, bit line contact GB is formed between the pair of select gate regions R1 which is followed by formation of multiple levels of interconnects to obtain a NAND flash memory.

The foregoing series of steps allows the spacing between select gate region R1 and memory cell gate region R2 to be controlled as desired which in turn allows control of the spacing between select gate electrode SG and memory cell gate electrode MG.

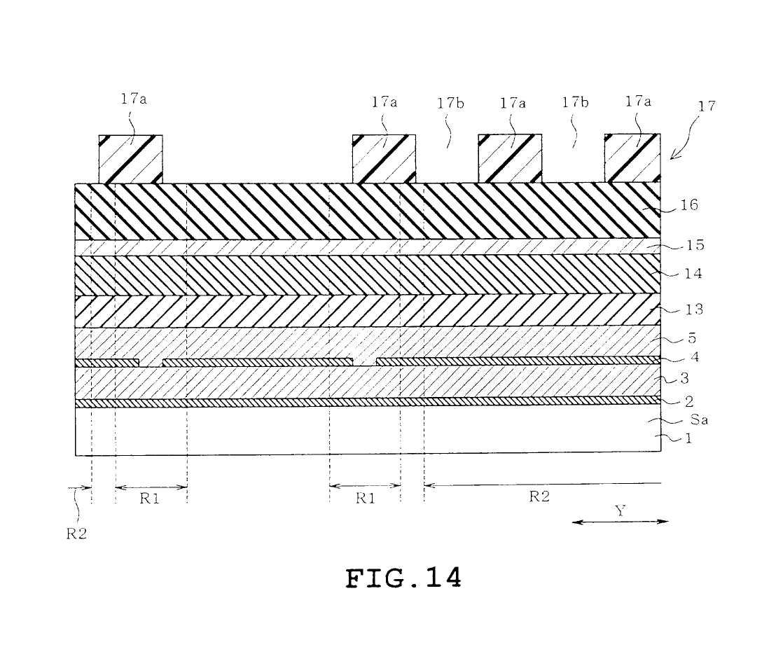

FIGS. 14 to 22 illustrate a second embodiment. The second embodiment performs another SWT prior to obtaining the structure illustrated in FIG. 5 of the first embodiment to reduce the width of line pattern 8a of silicon oxide film 8 also referred to as the second film. The elements that are identical to those of the first embodiment are represented by identical reference symbols and description will only be given on the differences from the first embodiment.

FIGS. 14 to 22 illustrate the additional manufacturing process flow carried out before the structure of FIG. 5 is obtained.

As shown in FIG. 14, gate insulating film 2, polysilicon film 3, intergate insulating film 4, polysilicon film 5 are laminated in the listed sequence above semiconductor substrate 1 by CVD as was the case in the first embodiment. Then, silicon nitride film 13 also referred to as a first film and second oxide film 14 also referred to as a second film are further laminated by CVD in the listed sequence. Silicon oxide film 14 corresponds to silicon oxide film 8 of the first embodiment.

Next, the second embodiment further laminates amorphous silicon film 15 serving as a mask and silicon oxide film 16 serving as a core in SWT and also referred to as a third film in the listed sequence by CVD. Then, a resist is coated above silicon oxide film 16 and thereafter patterned to form resist pattern 17.

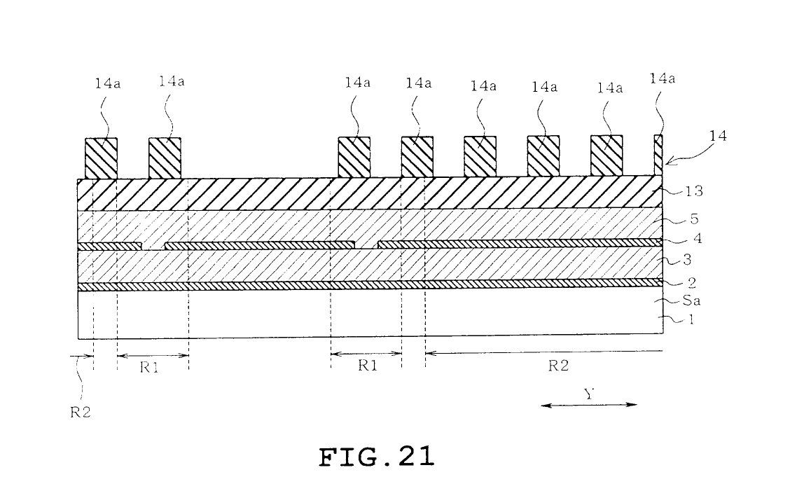

Resist pattern 17 can be patterned substantially at the resolution limit of a normal photolithography process. Accordingly, the width of line pattern 14a subsequently patterned in silicon oxide film 14 can be made narrower than the resolution limit of a normal lithography process as can be seen in FIG. 21. The foregoing series of steps allows formation of narrow gate electrodes MG.

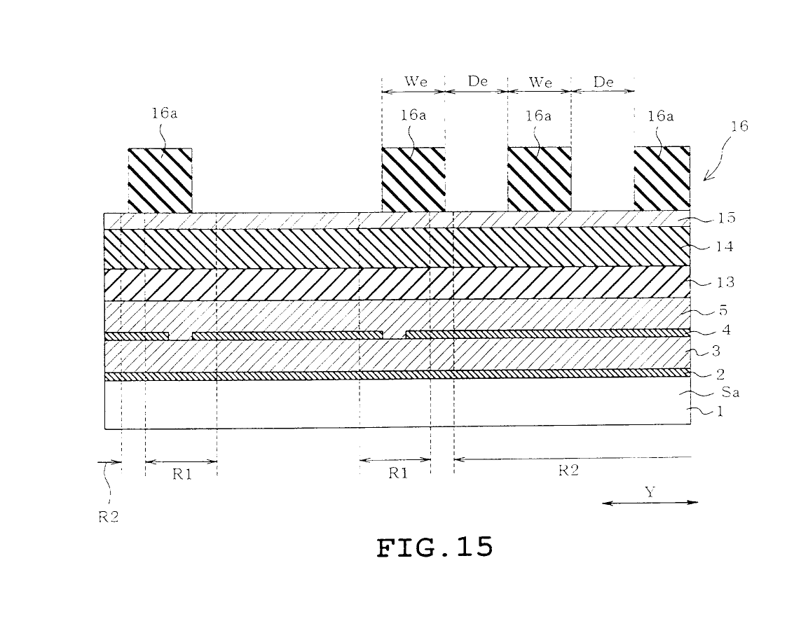

Then, as shown in FIG. 15, resist pattern 17 is used as a mask to anistropically etch silicon oxide film 16 typically by RIE. As a result, silicon oxide film 16 is patterned into a line and space pattern in which width of line pattern 16a is represented by We and spacing between the adjacent line patterns 16a is represented by De, where width We and spacing De are substantially equal. Spacing De between each of line patterns 16a is substantially constant. Dimensioning the line and space pattern such that width We and spacing De establish a 1:1 ratio is favorable to facilitate microfabrication.

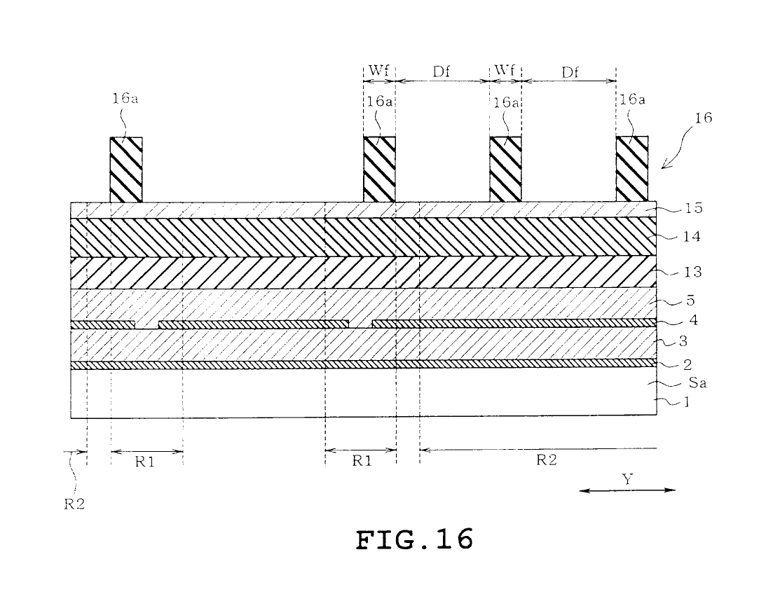

Next, as shown in FIG. 16, the sidewall of line pattern 16a is slimmed typically by wet etching. As a result, silicon oxide film 16 is patterned into a line and space pattern in which width of line pattern 16a is represented by Wf and spacing between the adjacent line patterns 16a is represented by Df, where width Wf<width We and spacing De<spacing Df. In the second embodiment, the ratio of width Wf to spacing Df may be controlled substantially at 1:3. As shown in FIG. 16, one of the slimmed patterns 16a has sidewall that substantially coincides with the edge of select gate region R1.

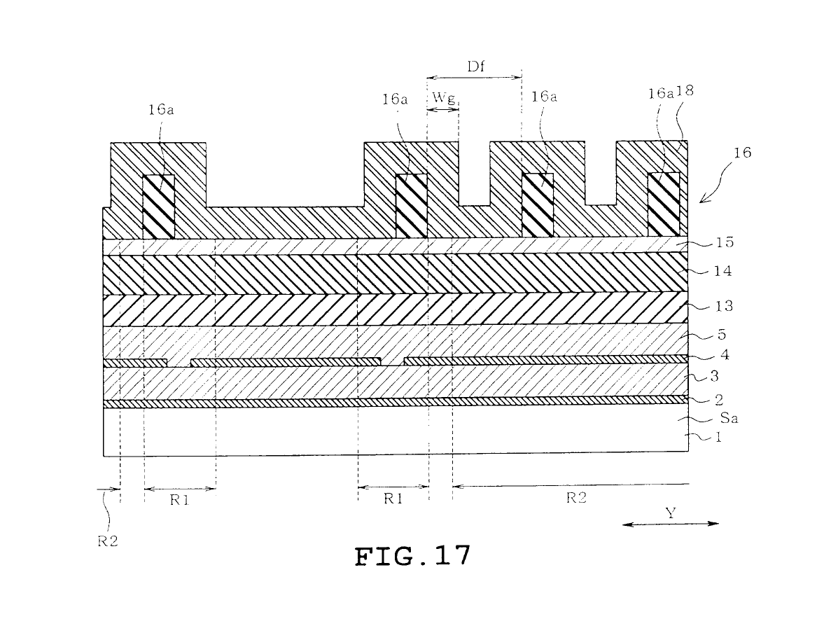

Then, as shown in FIG. 17, silicon nitride film 18 also referred to as a fourth film is conformally blanketed in thickness Wg along the sidewalls and the upper surfaces of line pattern 16a as well as the upper surface of silicon oxide film 15 by CVD.

Thickness Wg may be controlled so as to be smaller than spacing Df. The second embodiment exemplifies thickness Wg being controlled to substantially equal spacing Df/3, i.e. thickness Wg spacing Df/3.

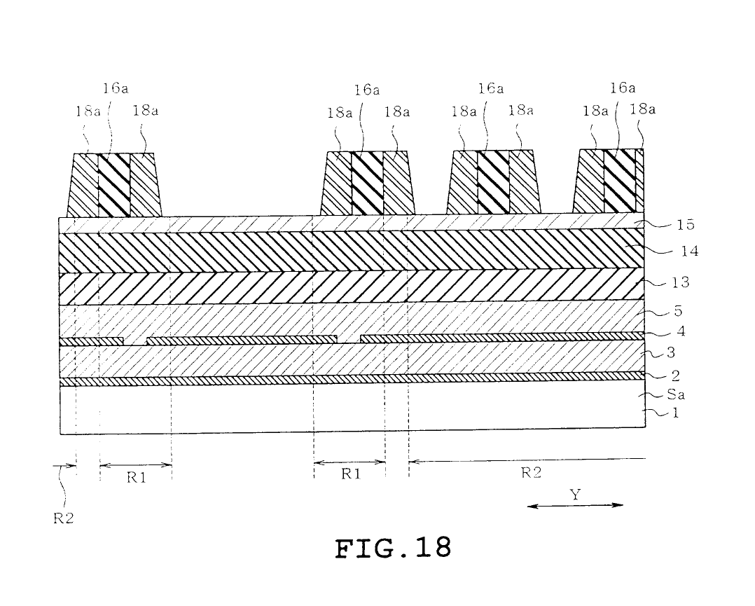

Then, as shown in FIG. 18, silicon nitride film 18 formed along the upper surface of line pattern 16a and along the central portion of the gap between the adjacent line patterns 16a is removed. As a result, silicon nitride film 18 remains along the sidewall of line pattern 16a as line pattern 18a serving as a spacer. Silicon nitride film 18 is employed as a spacer because silicon nitride film 18 is relatively harder than other candidate materials such as amorphous silicon and silicon oxide.

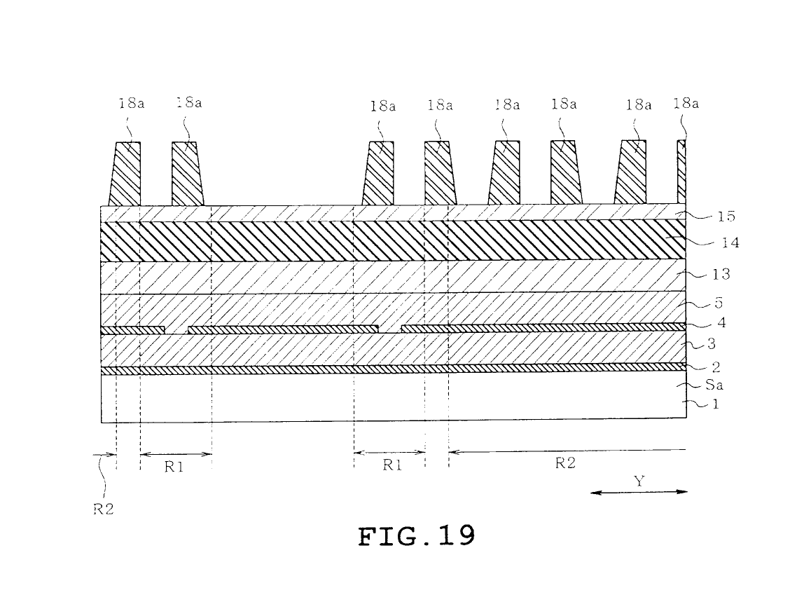

Next, as shown in FIG.19, line pattern 16a is removed by wet etching with higher selectivity to polysilicon film 15 and silicon nitride film 18.

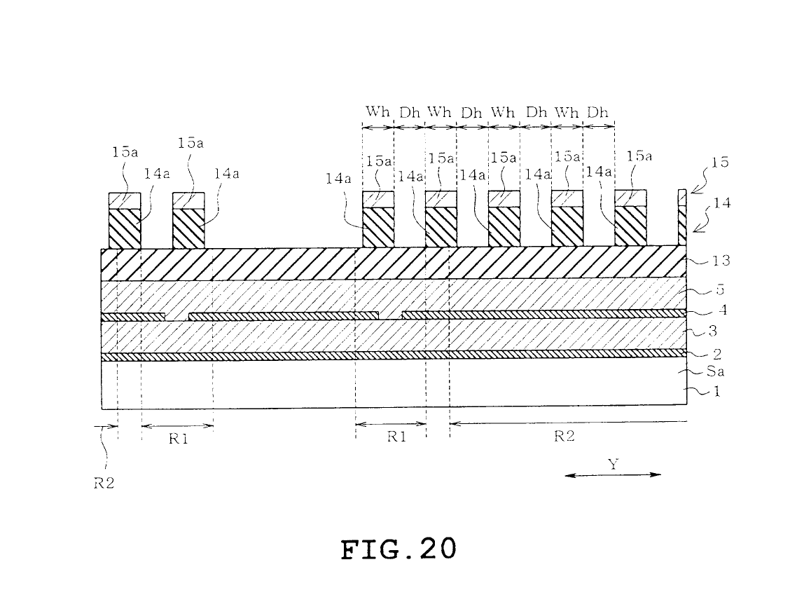

Next, as shown in FIG. 20, silicon nitride film 18 is used as a mask to remove polysilicon film 15 and silicon oxide film 14 by anisotropic RIE. Thus, line patterns 14a and 15a comprising a laminate of silicon oxide film 14a and polysilicon film 15 can be obtained. Though the second embodiment removes silicon nitride film 18 after etching silicon oxide film 14, the removing of silicon nitride film 18 is not mandatory at this stage.

Then, as shown in FIG. 21, line pattern 15a is removed by wet etching. The wet etching of line pattern 15a shown in FIG. 21 is not mandatory at this stage.

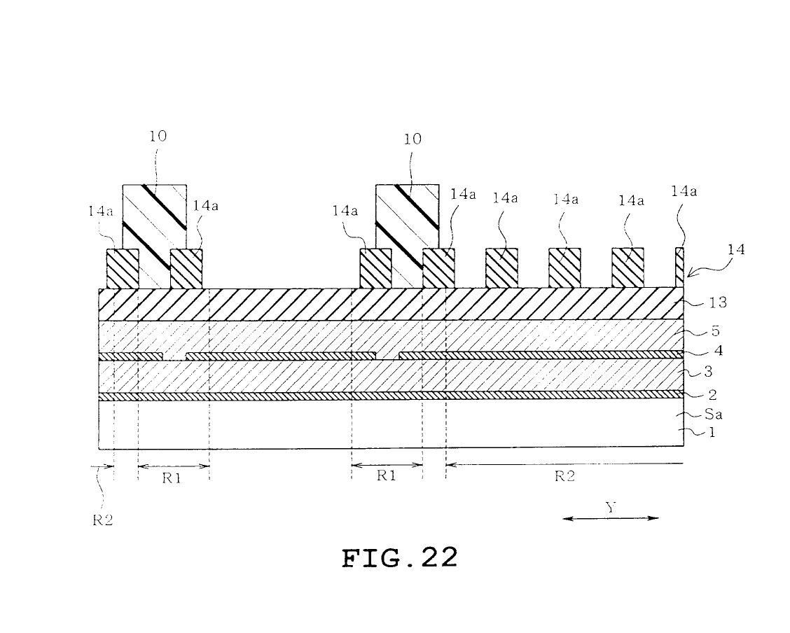

Next, as shown in FIG. 22, resist pattern 10 is formed so as to lie across line pattern 14a within select gate region R1 and line pattern 14a adjacent to it. The structure illustrated in FIG. 22 is substantially identical to FIG. 6 of the first embodiment. Subsequent steps, being identical to those of the first embodiment, will not be described.

Width Wh of Line pattern 14a formed during the manufacturing process flow of the structures illustrated in FIGS. 20 and 21 is narrower as compared to width We of line pattern 16a. Hence, line pattern 14a can be reduced in size by narrowing width We of line pattern 16a.

Second embodiment allows two iterations of SWT by applying the steps illustrated in FIGS. 6 to 13 of the first embodiment to line pattern 14a. Thus, the second embodiment employs a double sidewall transfer process to further reduce the width of the resulting gate electrodes MG and SG.

The foregoing manufacturing process flow provides operation and effect similar to those of the first embodiment and allows formation of smaller line pattern 14a as compared to the line pattern of the first embodiment.

The foregoing embodiments may be modified or expanded as follows.

Apart from the foregoing embodiments directed to a NAND flash memory, embodiments directed to other nonvolatile semiconductor storage devices provided with select gate electrodes of select transistors and memory cell gate electrodes of memory cell transistors also fall within the scope of the application.

The gate electrodes may be configured by SONGS (silicon-oxide-nitride-oxide-semiconductor) structure or MONOS (metal-oxide-oxide-semiconductor) structure.

The combination of the first, second, third, and fourth film may be rearranged or further employ materials not mentioned in the embodiments as long as proper selectivity is established between the films during etching. The use of silicon oxide film, silicon nitride film, amorphous silicon film employed in the foregoing embodiments is preferable. Employing silicon nitride film as the spacer or the sidewall film is more suitable for microfabrication as it is harder as compared to the rest of the foregoing materials.

Between select gate electrode SG of select transistor Trs1 and memory cell gate electrode MG of memory cell transistor Trm, several dummy gate electrodes, such as 1 to 3 in number, of dummy transistors may be provided. Dummy transistors are used for control ling the threshold voltage of memory cell transistor Trm. A dummy gate electrode may also be referred to as the second gate electrode and a dummy transistor may also be referred to as the second transistor.

Impurity diffusion region 6 may be omitted or replaced by alternative structures if memory cell transistor Trm, select gate transistors Trs1 and Trs2, bit line contact CB, and source line SL can be series connected. Examples of alternative structures include metal silicides such as a nickel silicide.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a nonvolatile semiconductor device, comprising:
preparing a semiconductor substrate having a first insulating film formed thereabove;
forming a charge storage layer above the first insulating film, the charge storage layer being used as a first gate electrode of a first transistor and as a second gate electrode of a second transistor;
forming a first film and a second film in the listed sequence above the charge storage layer;
patterning the second film into a line and space pattern including a plurality of line patterns and a plurality of space patterns;
applying a first mask lying across the line pattern located in a first region for forming the first gate electrode and the line pattern located in a second region for forming the second gate electrode;
slimming sidewalls of unmasked line patterns;
forming a blanket film across the first region and the second region and partially removing the blanket film so as to remain along the slimmed sidewalls of the line patterns;
applying a second mask above the Line patterns located in the first region and removing the line patterns located in the second region such that the masked line patterns located in the first region remain;
anisotropically etching the first film using the blanket film and the remaining line patterns as a mask; and
etching the charge storage layer using the first film as a mask to form the first and the second gate electrodes.

2. The method according to claim 1, wherein forming the first and the second film is followed by formation of a third film above the second film, and patterning includes:
patterning the third film into a line and space pattern including a plurality of line patterns and a plurality of space patterns, and
slimming sidewalls of the patterned third film, and wherein patterning is followed by:
forming a fourth film along the sidewalls of the slimmed third film,
removing the third film, and
patterning the second film into a line and space pattern including a plurality of line patterns and a plurality of space patterns using the fourth film as a mask.

3. The method according to claim 1, wherein the patterning includes forming the line patterns of a constant width.

4. The method according to claim 1, wherein the patterning includes forming the space patterns of a constant width.

5. The method according to claim 1, wherein patterning includes forming the line pasterns and the space patterns in an equal width.

6. The method according to claim 1, wherein the first gate electrode comprises a select gate electrode of a select transistor and the second gate electrode comprises a memory cell gate electrode of a memory cell transistor.

7. The method according to claim 1, wherein the first gate electrode comprises a select gate electrode of a select transistor and the second gate electrode comprises a gate electrode of a dummy transistor used for controlling threshold of a memory cell transistor.

8. The method according to claim 1, wherein the blanket film is formed at a thickness that satisfies:
2×thickness Wd≈spacing Da, and
3×thickness Wd≈spacing Dc,
where thickness Wd represents the thickness of the blanket film,
spacing Da represents a spacing between the line pattern located in the first region and the line pattern located in the second region, and
spacing Dc represents a spacing between the line patterns located in the second region.

9. The method according to claim 2, wherein a thickness of the fourth film is formed at a thickness that satisfies:
thickness Wg<spacing Df,
where thickness Wg represents the thickness of the fourth film, and
spacing Df represents a spacing between the line patterns of the slimmed third film.

10. The method according to claim 9, wherein thickness Wg≈spacing Df/3.

11. The method according to claim 2, wherein the fourth film comprises a silicon nitride film.

12. The method according to claim 1, wherein the first mask lies across the line pattern located in the first region and the nearest adjacent line pattern located in the second region.
